(19) United States
(12) Patent Application Publication
(10) Pub. No.: US 2021/0102462 A1
(43) Pub. Date: Apr. 8, 2021

(54) OPTIMIZATION APPARATUS, SYSTEM AND METHOD FOR RESOURCE PRODUCTION SYSTEM

(71) Applicant: General Electric Company, Schenectady, NY (US)

(72) Inventors: Yu RU, Shanghai (CN); Tong ZHAO, Shanghai 31 (CN); Rogier Sebastiaan BLOM, Niskayuna, NY (US)

(21) Appl. No.: 16/607,963

(22) PCT Filed: Apr. 13, 2018
(86) PCT No.: PCT/US2018/027461

§ 371 Date: Oct. 24, 2019

(30) Foreign Application Priority Data
Apr. 24, 2017 (CN) 201710270656.9

(51) Int. Cl. E21B 49/08; E21B 47/09; E21B 47/12

(52) U.S. Cl. CPC E21B 49/0875; E21B 47/138; E21B 47/09

(57) ABSTRACT

An optimization apparatus for optimizing an objective function of a resource production system, comprising: an analytical model of the resource production system configured to receive data from the resource production system, the analytical model comprising a reservoir model, a plurality of well models coupled to the reservoir model, and a surface pipeline model coupled to the plurality of well models, wherein the plurality of well models comprise a first set of segments associated with a first set of operating parameters; and an optimization module configured to vary a set of variable parameters of the analytical model and satisfy a set of pre-determined constraints to optimize an objective function of the resource production system, wherein running the optimization includes calculating pressures of each of the first set of segments based on the analytical model. An optimization method and system are also described.

### BACKGROUND

This invention relates generally to an optimization apparatus, system and method for resource production system.

Underground resource, such as petroleum, is generally produced by drilling wells through earth formations having resource reservoirs therein, and causing resource fluids in the reservoir to move to the surface of earth through the wells. Usually, to obtain a desired production result, e.g., a higher total production or a better economic benefit, one or more assemblies, such as pumps and chokes, are usually provided to adjust flow rates of fluids in the wells.

In the art, it is common to model an underground resource production system to determine a proper optimal solution so as to achieve the desired production result. However, in one aspect, as the flow rates of fluids are influenced by various factors, the time cost of computing a proper optimal solution is almost unacceptable, especially for those production systems with a large number of wells. In another aspect, as well interference is usually not considered in the model, the accuracy of the results obtained based on the model is usually quite low.

Therefore, it would be desirable to provide new and improved optimization apparatus, system and method for resource production system.

### BRIEF DESCRIPTION

In one aspect, the present disclosure relates to an optimization apparatus for optimizing an objective function of a resource production system, comprising: an analytical model of the resource production system configured to receive data from the resource production system, the analytical model comprising a reservoir model, a plurality of well models coupled to the reservoir model, and a surface pipeline model coupled to the plurality of well models, wherein the plurality of well models comprise a first set of segments associated with a first set of operating parameters; and an optimization module configured to vary a set of variable parameters of the analytical model and satisfy a set of pre-determined constraints to optimize an objective function of the resource production system, wherein running the optimization includes calculating pressures of each of the first set of segments based on the analytical model.

In another aspect, the present disclosure relates to an optimization method for optimizing an objective function of a resource production system, comprising: establishing an analytical model of the resource production system for receiving data from the resource production system, the analytical model comprising a reservoir model, a plurality of well models coupled to the reservoir model, and a surface pipeline model coupled to the plurality of well models, wherein the plurality of well models comprise a first set of segments associated with a first set of operating parameters; and varying a set of variable parameters of the analytical model and satisfy a set of pre-determined constraints to optimize an objective function of the resource production system, wherein running the optimization includes calculating pressures of each of the first set of segments based on the analytical model.

In yet another aspect, the present disclosure relates to an optimization system for a resource production system comprising a plurality of wells, comprising: a well management system configured to communicate with the plurality of wells; and an optimization apparatus configured to communicate with the well management system, comprising: an analytical model of the resource production system configured to receive data from the resource production system, the analytical model comprising a reservoir model, a plurality of well models coupled to the reservoir model, and a surface pipeline model coupled to the plurality of well models, wherein the plurality of well models comprise a first set of segments associated with a first set of operating parameters; and an optimization module configured to vary a set of variable parameters of the analytical model and satisfy a set of pre-determined constraints to optimize an objective function of the resource production system, wherein running the optimization includes calculating pressures of each of the first set of segments based on the analytical model; wherein, the optimization module provides a result of the optimization to the well management system, and the well management system communicates with the plurality of wells to perform a production optimization based on the result of the optimization.

### BRIEF DESCRIPTION OF THE DRAWINGS

The above and other aspects, features, and advantages of the present disclosure will become more apparent in light of the following detailed description when taken in conjunction with the accompanying drawings in which:

FIG. 1 is a schematic view of an optimization apparatus in accordance with an embodiment of the present invention;

FIG. 2 is a schematic view of a reservoir and a resource production system in accordance with an embodiment of the present invention;

FIG. 3 is a schematic view of an analytical model in accordance with an embodiment of the present invention;

FIG. 4 is a schematic view of tendencies of the changes of pressures at the node 13 and 14 shown in the FIG. 3 with respect to a change of flow rate;

FIG. 5 is a schematic view of the analytical model in accordance with another embodiment of the present invention;

FIG. 6 is a schematic view of tendencies of the changes of pressures at the node 11 and 12 shown in the FIG. 5 with respect to a change of flow rate;

FIG. 7 is a schematic flow diagram of an optimization method in accordance with an embodiment of the present invention;

FIG. 8 is a schematic flow diagram of an optimization method in accordance with another embodiment of the present invention; and

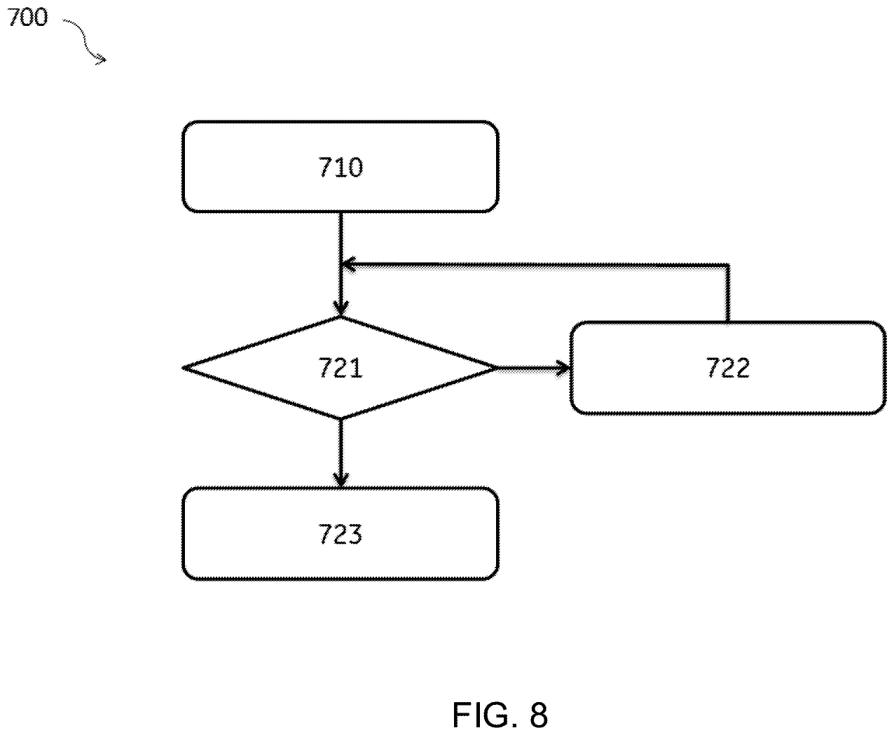

FIG. 9 is a schematic view of an optimization system communicated with a resource production system in accordance with an embodiment of the present invention.

### DETAILED DESCRIPTION

In an effort to provide a concise description of these embodiments, not all features of an actual implementation are described in one or more specific embodiments. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of the present disclosure.

Unless defined otherwise, technical and scientific terms used herein have the same meaning as is commonly understood by one of ordinary skill in the art to which the present disclosure belongs. The terms “first,” “second,” and the like, as used herein do not denote any order, quantity, or importance, but rather are used to distinguish one element from another. Also, the terms “a” and “an” do not denote a limitation of quantity, but rather denote the presence of at least one of the referenced items. The term “or” is meant to be inclusive and mean either any, several, or all of the listed items. The use of “including”, or “comprising” and variations thereof herein are meant to encompass the items listed thereafter and equivalents thereof as well as additional items.

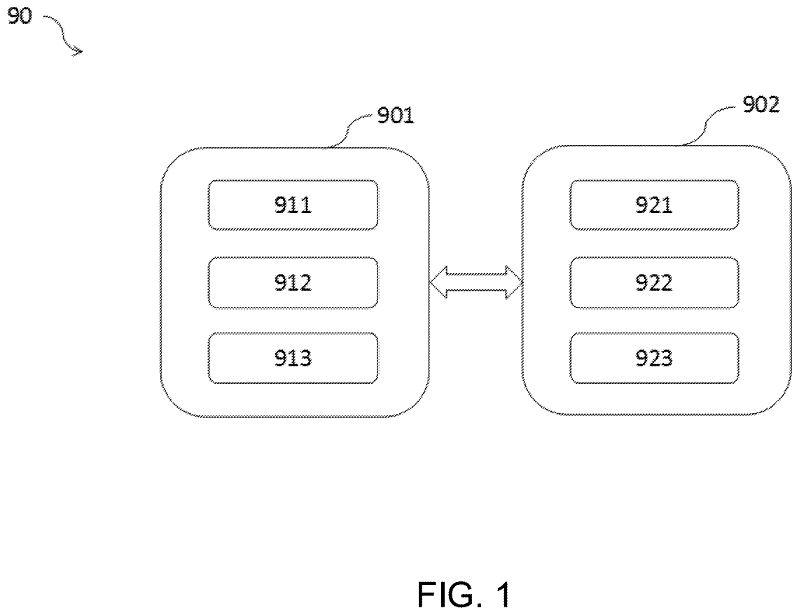

FIG. 1 illustrates a schematic view of an optimization apparatus 90 for optimizing an objective function of a resource production system in accordance with an embodiment of the present invention. The resource production system comprises but is not limited to an oil production system, etc. The optimization apparatus 90 comprises an analytical model 901 and an optimization module 902.

The analytical model 901 comprises a reservoir model 911, a plurality of well models 912 coupled to the reservoir model 911, and a surface pipeline model 913 coupled to the plurality of well models 912. The analytical model 901 also comprises invariant parameters and variable parameters.

The reservoir model 911 simulates an underground reservoir, e.g., an underground oil reservoir. Based on the reservoir model 911, a pressure of the bottom of a well model of the plurality of well models 912 may be determined.

The plurality of well models 912 simulate a plurality of wells of the resource production system for artificially lifting fluids from a reservoir to the surface. In some embodiments, the plurality of well models 912 are associated with a set of flow rates indicating flow rates in a plurality of wells of the resource production system. The surface pipeline model 913 simulates the surface pipeline of the resource production system for commingling and transporting fluids from the plurality of wells.

The plurality of well models 912 and the surface pipeline model 913 comprise segments and nodes. The segment may indicate an assembly in the resource production system, e.g., the segment may indicate a pipe, an operable assembly such as a pump or a choke, etc. The node may indicate the connection point of a plurality of segments, the connection point of the segment and the reservoir model 911, etc. The segment and/or node may be associated with one or more parameter. For example, the segment indicating a pipe may be associated with some invariant parameters such as length, diameter, roughness of the pipe; the segment indicating an operable assembly, such as a pump or a choke, may be associated with a variable parameter, e.g., an operating parameter such as a pump drive parameter or a choke opening, of the operable assembly; the node may be associated with a variable parameter such as a pressure, a temperature, etc. The pump drive parameter is associated with the pump, and the change of the value of the pump drive parameter usually cause a change of flow rate of the fluid passing though the pump. In some embodiments, the pump drive parameter comprises but is not limited to a pump speed, a pump frequency, etc.

In some embodiments, the plurality of well models 912 comprise at least one set of segments associated with at least one set of operating parameters respectively; in some embodiments, each of the at least one set of segments may be associated with a plurality of sets of operating parameters. The segments in the same set indicate the same kind of assemblies. For example, the plurality of well models 912 comprise a set of segments indicating pumps (hereinafter, “set of segments indicating pumps” is referred to as “set of pumps”) for artificial lift and the set of pumps are associated with a set of pump drive parameters. The plurality of well models 912 may further comprise a set of segments indicating chokes (hereinafter, “set of segments indicating chokes” is referred to as “set of chokes”) and the set of chokes are associated with a set of choke openings.

In some embodiments, the analytical model 901 further comprises a fluid property model (not shown) and a fluid commingling model (not shown). The fluid property model may comprise the fluid characteristics such as density, viscosity, surface tension, volumetric flow rate of fluid, etc. In some embodiments, the fluid property model may be coupled with the surface pipeline model 913 and indicate fluid characteristics associated with the surface pipeline model 913; in some embodiments, the fluid property model may further be coupled with the plurality of well models 912, and further indicate the fluid characteristics associated with the plurality of well models 912; in some embodiments, the fluid property model may further be coupled with the reservoir model 911, and further indicate the fluid characteristics associated with the reservoir model 911. The fluid commingling model simulates a change of fluid characteristics relating to a fluid commingling, such as a change of density, viscosity, surface tension, volumetric flow rate relating to a fluid commingling. For example, if inputting fluids characteristics of several fluids to the fluid commingling model, the fluid commingling model may output fluid characteristics of a fluid commingled by the several fluids. In some embodiments, the fluid commingling model is coupled with the surface pipeline model 913.

The optimization module 902 varies a set of variable parameters of the analytical model 901 and satisfy a set of pre-determined constraints to optimize an objective function of the resource production system.

The objective function indicates a production objective of the resource production system. A result of the objective function may be calculated based on the analytical model 901 with the set of variable parameters. Therefore, through varying the set of variable parameters, a plurality of results of the objective function may be obtained to determine a result of optimization of the objective function. In some embodiments, the objective function comprises but is not limited to an output of the resource production system, an energy consumption of the resource production system, a cost of operating the resource production system, or a benefit of the resource production system.

The set of pre-determined constraints constrains the optimization run by the optimization module 902 so that a result of the optimization may be achieved in actual production process of the resource production system. For example, the operating parameter in actual production process is limited within a range for a normal operation of a corresponding operable assembly. For another example, a proper range of the flow rate is usually desired in actual production process because of various considerations such that an improperly high flow rate in a well may lead to a larger influence of production of neighboring wells. In some embodiments, the set of constraints comprises but is not limited to a minimum or maximum threshold of the objective function, a range for a set of operating parameters of the analytical model 901, a range for a set of variable parameters of the analytical model 901, a range for a nodal pressure of a pre-determined node in the analytical model 901, a range for a fluid property of a pre-determined node in the analytical model 901, a range of flow rate of a pre-determined node in the analytical model 901, a range for power consumption associated with a pre-determined segment in the analytical model 901, or any combination thereof.

Please be noted that, as a desired range may be different depending on an actual production environment, a conversion may be utilized before the optimization module 902 determines whether a range in the set of pre-determined constraints is satisfied. For example, the range for the pump drive parameter in the set of pre-determined constraints indicates a proper or possible range suitable for pumping water, then this range needs to be converted to a range suitable for pumping fluids before it is used to determine whether a calculated operating parameter satisfies the pre-determined constraint. The method of such a kind of conversion is well known in the art.

In some embodiment, the varied set of variable parameters comprises a set of flow rates. Running the optimization comprises calculating pressures of each of a first set of segments of the plurality of well models 912 based on the analytical model 901 with the set of flow rates. In some embodiments, running the optimization further comprises calculating a first set of operating parameters associated with the first set of segments based on the calculated pressures and a model of each of the first set of segments. In some embodiments, the optimization module 902 calculates a pressure of an upstream side of each of the first set of segments based on the analytical model 901 with the set of flow rates and a pressure of a pre-determined node upstream from the upstream side, calculates a pressure of a downstream side of each of the first set of segments based on the analytical model 901 with the set of flow rates and a pressure of a pre-determined node downstream from the downstream side, and calculates the first set of operating parameters based on the calculated pressures of the upstream and downstream sides and a model of each of the first set of segments. Herein, the direction of “downstream” is the direction along the flow of the fluids, and the direction of “upstream” is the direction opposite to the flow of the fluids.

The pressure of the pre-determined node upstream from the upstream side may be pre-set or be calculated based on the reservoir model 911. In some embodiments, the interference between wells is considered, the reservoir model 911 comprises an interference function for indicating the interference between neighboring wells, thus the flow rates associated with the neighboring well models are necessary for calculating the pressure of the pre-determined node upstream from the upstream side.

The pressure of the pre-determined node downstream from the downstream side may be pre-set or be determined based on data from a sensor in the resource production system. For example, the resource production system comprises a sensor for detecting a pressure of a separator connecting with the surface pipeline of the resource production system to receive fluids from the surface pipeline and separate gases in the fluids from liquids or solid-liquid mixtures in the fluids, and data from the sensor are provided to the optimization apparatus 90 so that the optimization apparatus 90 determines a pressure of a node indicating the separator based on the data. In some embodiments, the interference of commingling fluids in the surface pipeline is considered, and the fluid property model, the fluid commingling model, and the surface pipeline model 913 are utilized while calculating the pressures of each of the first set of segments.

In some embodiments, the plurality of well models 912 comprise a second set of segments associated with a second set of operating parameters. The varied set of variable parameters comprises the set of flow rates and the second set of operating parameters. Running the optimization comprises calculating pressures (e.g., pressures of the upstream side and the downstream side) of each of a first set of segments of the plurality of well models 912 based on the analytical model 901 with the set of flow rates and the second set of operating parameters. In some embodiments, running the optimization further comprises calculating a first set of operating parameters associated with the first set of segments based on the calculated pressures and a model of each of the first set of segments.

In some embodiments, the first set of segments comprises one set of a set of pumps and a set of chokes, and the second set of segments comprises the other set of the set of pumps and the set of chokes. The set of pumps is associated with the set of pump drive parameters, and the set of chokes is associated with the set of choke openings. Please be noted that, in some embodiments, the analytical model 901 may comprise segments indicating operable assemblies other than pumps and chokes, and the first and second set of segments may be the set of segments indicating operable assemblies other than pumps and chokes.

The optimization module 902 may comprise a plurality of units to achieve various functions. In some embodiments, the optimization module 902 comprises an analyzing unit 921, an optimizing unit 922 and an invoking unit 923.

The analyzing unit 921 receives a set of feasible variable parameters from the optimizing unit 922, calculates pressures of each of the first set of segments based on the analytical model 901 with the feasible set of flow rates. In some embodiments, the analyzing unit 921 further calculates the first set of operating parameters based on the model of each of the first set of segments. In some embodiments, the set of feasible variable parameters comprises a set of flow rates.

The optimizing unit 922 varies the set of variable parameters associated with the plurality of well models to obtain the feasible set of variable parameters and provide the feasible set of variable parameters to the analyzing unit 921 to obtain the calculated first set of operating parameters from the analyzing unit 921 while satisfying the set of pre-determined constraints.

The invoking unit 923 iteratively invokes the analyzing unit 921 and the optimizing unit 922 till a termination criterion is met.

In some embodiments, the termination criterion comprises that the optimized objective function satisfies a production target of the resource production system and the set of pre-determined constraints is satisfied.

The production target may relate to an output of the resource production system, an energy consumption of the resource production system, a cost of operating the resource production system, or a benefit of the resource production system. For example, the production target includes but is not limited to a relative large value of the output or the benefit of the resource production system compared with a pre-determined threshold value, or a relative small value of the energy consumption or the cost of operating of the resource production system compared with a pre-determined threshold value. For another example, the production target includes but is not limited to a largest value of the output or the benefit of the resource production system available by varying the set of variable parameters, or a smallest value of the energy consumption or the cost of operating of the resource production system available by varying the set of variable parameters. As a variation tendency of the output, the benefit, the energy consumption or the cost of operating of the resource production system while varying the set of variable parameters is known in the art, it may be therefore determined whether the output, the benefit, the energy consumption or the cost of operating is the largest or smallest based on the variation tendency. For example, if a difference value between outputs calculated based on the current varied set of variable parameters and the last varied set of variable parameters is less than a pre-determined difference threshold value, the output calculated based on the current varied set of variable parameters may be regarded as the largest.

Hereinafter, more detailed embodiments are introduced to further describe the optimization apparatus 90.

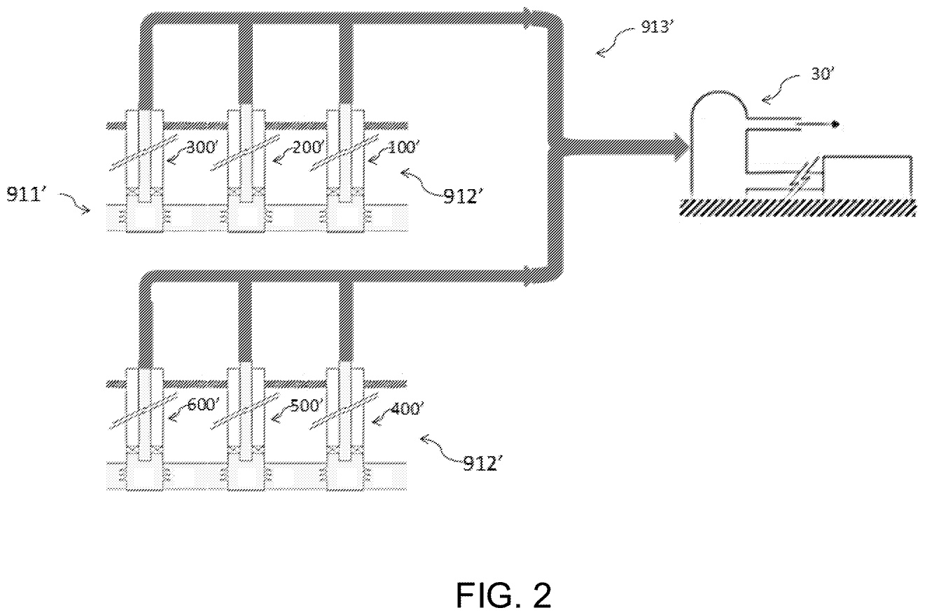

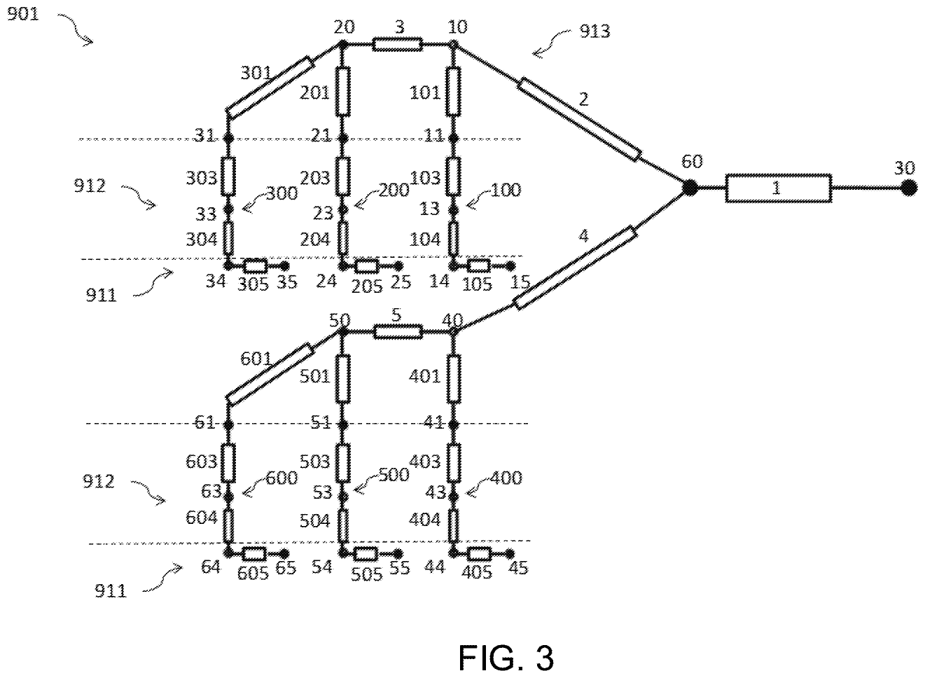

Please refer to FIGS. 1-3. FIG. 2 illustrates a reservoir 911′ and a resource production system for obtaining fluids from the reservoir 911′ based on artificial lift. The resource production system comprises a surface pipeline system 913′ and a plurality of wells 100′, 200′, 300′, 400′, 500′ and 600′. The surface pipeline system 913′ transmits the fluids to a separator 30′ for separating gases from liquids or solid-liquid mixtures. FIG. 3 illustrates an analytical model 901 comprising a reservoir model 911 simulating the reservoir 911′, a plurality of well models 912 including well models 100, 200, 300, 400, 500 and 600 respectively simulating the plurality of wells 100′, 200′, 300′, 400′, 500′ and 600′, and a surface pipeline model 913 simulating the surface pipeline system 913′.

The dashed lines in FIG. 3 are for better illustrating the reservoir model 911, the plurality of well models 912 and the surface pipeline model 913, and have no actual meaning.

The well model 100 comprises a segment 103 indicating a pipe (hereinafter, “segment 103” is referred to as “pipe 103” and all the segments are referred to as “assembly name XXX”, wherein “assembly name” is the name of assembly indicated by the segment and “XXX” is the reference numeral of the segment) and a pump 104, and a node 13 indicates the connection point of the pipe 103 and the pump 104. Similarly, the well model 200 comprises a pipe 203 and a pump 204, and a node 23 indicates the connection point of the pipe 203 and the pump 204; the well model 300 comprises a pipe 303 and a pump 304, and a node 33 indicates the connection point of the pipe 303 and the pump 304; the well model 400 comprises a pipe 403 and a pump 404, and a node 43 indicates the connection point of the pipe 403 and the pump 404; the well model 500 comprises a pipe 503 and a pump 504, and a node 53 indicates the connection point of the pipe 503 and the pump 504; the well model 600 comprises a pipe 603 and a pump 604, and a node 63 indicates the connection point of the pipe 603 and the pump 604.

A set of pumps [104, 204, 304, 404, 504, 604] are associated with a set of pump drive parameters [V₁, V₂, V₃, V₄, V₅, V₆], and pump drive parameters V₁, V₂, V₃, V₄, V₅ and V₆ are associated with pumps 104, 204, 304, 404, 504 and 604 respectively.

The surface pipeline model 913 comprises a pipe 1, 2, 3, 4, 5, 101, 201, 301, 401, 501 and 601. The pipe 101 is connected to the pipe 103 at a node 11, the pipe 201 is connected to the pipe 203 at a node 21, the pipe 301 is connected to the pipe 303 at a node 31, the pipe 401 is connected to the pipe 403 at a node 41, the pipe 501 is connected to the pipe 503 at a node 51, the pipe 601 is connected to the pipe 603 at a node 61. One side of the pipe 1 is connected with pipes 2 and 4 at a node 60, another side of the pipe 1 is marked as a node 30, and the pressure at the node 30 may indicate the pressure in the separator 30′; the pipes 2, 3 and 101 are connected with each other at a node 10; the pipes 3, 201 and 301 are connected with each other at a node 20; the pipes 4, 5 and 401 are connected with each other at a node 40; the pipes 5, 501 and 601 are connected with each other at a node 50.

The reservoir model 911 comprises reservoirs 105, 205, 305, 405, 505 and 605. The reservoir 105 is connected with the well model 100 at a node 14; the reservoir 205 is connected with the well model 200 at a node 24; the reservoir 305 is connected with the well model 300 at a node 34; the reservoir 405 is connected with the well model 400 at a node 44; the reservoir 505 is connected with the well model 500 at a node 54; the reservoir 605 is connected with the well model 600 at a node 64. The pressure at the nodes 15, 25, 35, 45, 55 and 65 may be the average reservoir pressure, which is usually pre-set.

A pipe in the surface pipeline model 913 and the well models 100, 200, 300, 400, 500 and 600 may be associated with parameters of pipe properties, such as a length, a diameter, a roughness of the pipe, etc. A pump in the well models 100, 200, 300, 400, 500 and 600 is associated with an operating parameter, e.g., the pump drive parameter. That is to say, pumps 104, 204, 304, 404, 504 and 604 are associated with a set of pump drive parameters, and each of pumps 104, 204, 304, 404, 504, 604 is associated with a pump drive parameter in the set of pump drive parameters.

In some embodiments, the analytical model 901 comprises a set of flow rates [F₁, F₂, F₃, F₄, F₅, F₆] associated with the plurality of well models 100, 200, 300, 400, 500 and 600, e.g., the flow rate F₁, F₂, F₃, F₄, F₅, F₆ are respectively associated with the well models 100, 200, 300, 400, 500 and 600. In some embodiments, the analytical model 901 further comprises a fluid property model and a fluid commingling model. The fluid property model comprises fluid characteristics (such as density, viscosity, surface tension, volumetric flow rate of fluid, etc.) of fluids in pipes of the surface pipeline model 913. The fluid commingling model simulates a change of fluid characteristics (such as a change of density, viscosity, surface tension, volumetric flow rate) relating to a fluid commingling in a pipe of the surface pipeline model 913.

The optimization module 902 varies the set of variable parameters of the analytical model 901 and satisfies the set of pre-determined constraints to optimize the objective function of the resource production system, wherein running the optimization includes calculating pressures of each of a set of pumps [104, 204, 304, 404, 504, 604] based on the analytical model 901. In some embodiments, running the optimization further includes calculating the set of pump drive parameters based on the calculated pressures and the model of each of the set of pumps [104, 204, 304, 404, 504, 604]. In some embodiments, the varied set of variable parameters is the set of flow rates [F₁, F₂, F₃, F₄, F₅, F₆].

In some embodiments, the optimizing unit 922 of the optimization module 902 varies the set of variable parameters to obtain a feasible set of variable parameters and provide the feasible set of variable parameters to the analyzing unit 921 of the optimization module 902. The analyzing unit 921 calculating pressures of each of the set of pumps [104, 204, 304, 404, 504, 604] based on the analytical model 901 with the feasible set of variable parameters, calculates the set of pump drive parameters based on the model of each of the set of pumps [104, 204, 304, 404, 504, 604], and provides the calculated set of pump drive parameters to the optimizing unit 922. The optimizing unit 922 receives the calculated set of pump drive parameters and determines whether the set of pre-determined constraints is satisfied. The invoking unit 923 of the optimization module 902 iteratively invokes the analyzing unit 921 and the optimizing unit 922 till the termination criterion is met.

In some embodiments, the pressures of each of the set of pumps [104, 204, 304, 404, 504, 604] comprises the pressures of the upstream side and the downstream side of each of the set of pumps [104, 204, 304, 404, 504, 604].

For example, the pressures of the pump 104 comprises the pressure of the upstream side (i.e., the pressure of the node 14) and the pressure of the downstream side (i.e., the pressure of the node 13).

The pressure of the node 13 may be calculated based on the pressure at the node 30, the flow rate F₁ associated with the well model 100, and the surface pipeline model 913. The pressure of the node 30 may be pre-set or obtained from a pressure sensor in the separator. Knowing the property of the pipe 103 obtained from the model of the pipe 103 and the flow rate F₁ of fluid passing through the pipe 103, a pressure drop in the pipe 103 (i.e., the pressure drop from the node 13 to the node 11) may be determined. Similarly, the pressure drops in the pipes 101, 2, 1 is determined, thus the pressure drop from the node 13 to the node 30 is determined. As the pressure at the node 30 is known, the pressure at the node 13 is then calculated.

In some embodiments, if without considering the interference in the surface pipeline, a pressure of the node located downstream from the node 13 may be used instead of the pressure at the node 30 while calculating the pressure at the node 13. For example, the pressure at the node 11 may be utilized instead of the pressure at the node 30, then, the pressure at the node 13 is calculated based on obtaining a pressure drop from the node 11 to the node 13, which may be calculated based on the flow rate F₁ and the property of the pipe 103. The pressure at the node 11 may indicate the pressure at a wellhead of the well 100′ and may be pre-set or obtained by a pressure sensor located at the wellhead.

In some embodiments, the interference in the surface pipeline is considered, the pressure of the node 13 may be calculated based on the pressure at the node 30, the set of flow rates [F₁, F₂, F₃, F₄, F₅, F₆], the surface pipeline model 913, the fluid property model and the fluid commingling model. Based on the flow rate F₁, the property of the pipes 101 and 103, the fluid properties in the fluid property model associated with the pipes 101 and 103, the pressure drops in the pipes 103 and 101 may be calculated. Fluids from the pipes 3 and 101 are commingled in the pipe 2. By imputing the properties of fluids associated with the pipes 3 and 101 to the fluid commingling model, the property of fluid associated with the pipe 2 is obtained. Then the pressure drop in the pipe 2 is calculated based on flow rates F₁, F₂, F₃, the property of the pipe 2, the property of fluid associated with the pipe 2. Similarly, the pressure drop in the pipe 1 is calculated based on the set of flow rates [F₁, F₂, F₃, F₄, F₅, F₆], the property of the pipe 1, the fluid properties associated with the pipes 2 and 4 and the fluid commingling model. Then the pressure drop from the node 13 to the node 30 is calculated and the pressure at the node 13 is determined.

The pressure of the node 14 may be calculated based on the pressure at the node 15, the flow rate F₁ and the reservoir model 911. The pressure at the node 15 may be pre-set. Without considering the interference between wells, the reservoir model 911 may output the pressure at the bottom of the well model 100, i.e., the pressure at the node 14, based on the flow rate F₁. If the interference between wells is considered, the reservoir model 911 may comprise a function for calculating the interference between neighboring wells, and may output the pressure at the bottom of the well model 100 based on the set of flow rates [F₁, F₂, F₃, F₄, F₅, F₆].

Known the pressures at the node 14 and node 13, the pressure increment of the pump 104 is calculated and the pump drive parameter V₁ of the pump 104 may be calculated based on the model of the pump 104 and the pressure increment utilizing, e.g., a root finding algorithm such as a binary search.

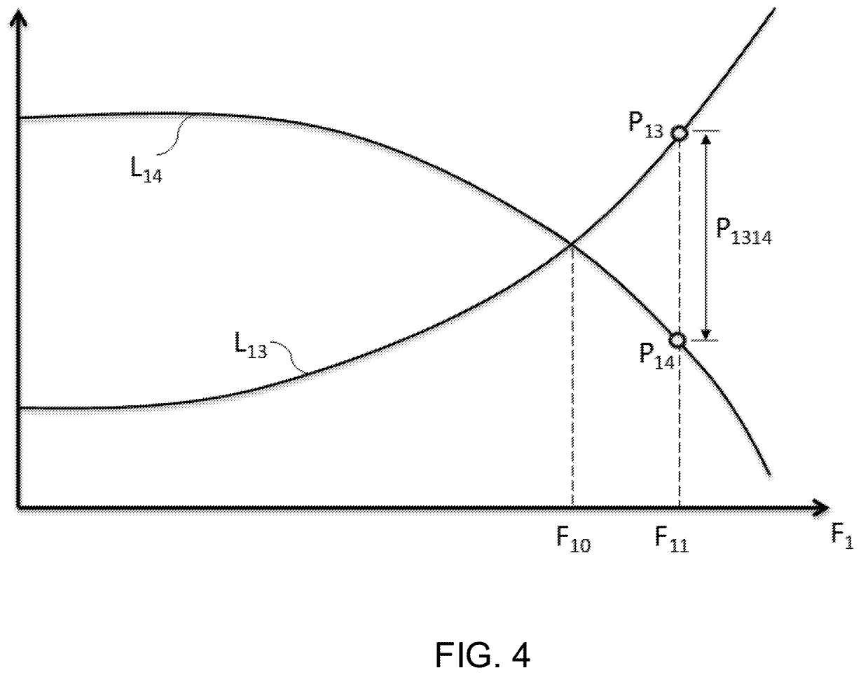

Please refer to FIGS. 3&4, wherein the X-axis of the coordinates shown in FIG. 4 indicates the flow rate F₁ and the Y-axis in FIG. 4 indicates pressure. Without considering the interference of commingling fluids in the surface pipeline and the interference between wells, a tendency of the change of pressure at the node 13 with respect to the change of flow rate F₁ is illustrated as line L₁₃ and the change of pressure at the node 14 with respect to the change of flow rate F₁ is illustrated as line L₁₄. The pressure at the node 13 increases while the flow rate F₁ increases, and the pressure at the node 14 drops while the flow rate F₁ increases. When F₁ is varied to F₁₁, the pressure P₁₃ and the pressure P₁₄ may be calculated as aforementioned, then the pressure increment P₁₃₁₄ of the pump 104 is determined. Please be noted that, for ensuring that the pressure at the node 13 is larger than the pressure at the node 14, the latest obtained flow rate F₁ (i.e., the flow rate F₁ in a result of the optimization performed by the optimization apparatus 90) should be larger than the flow rate F₁₀, at which the line L₁₃ intersects with the line L₁₄.

Please back to FIGS. 1&3. The calculation of the pump drive parameters V₂, V₃, V₄, V₅ and V₆ are similar with the calculation of the pump drive parameter V₁.

Varying the set of variable parameters and satisfying the set of pre-determined constraints to optimize the objective function of the resource production system is greatly helpful to obtain a desired production result. Especially, varying the set of flow rates and based on calculating pressures of each of the first set of segments and calculating the first set of operating parameters associated with the first set of segments to optimize the objective function brings a significant contribution to reduce time cost of obtaining a result of optimization. In some embodiments, compared with the time cost of obtaining the result of optimization based on varying the set of operating parameters, the time cost of obtaining the result of optimization based on varying the set of flow rates may be several times less. Moreover, considering the interference, a better result of optimization may be obtained. For example, the optimized pump drive parameters without considering the interference is very likely lower than the optimized pump drive parameters considering the interference, and the output without considering the interference is very likely lower than the output considering the interference.

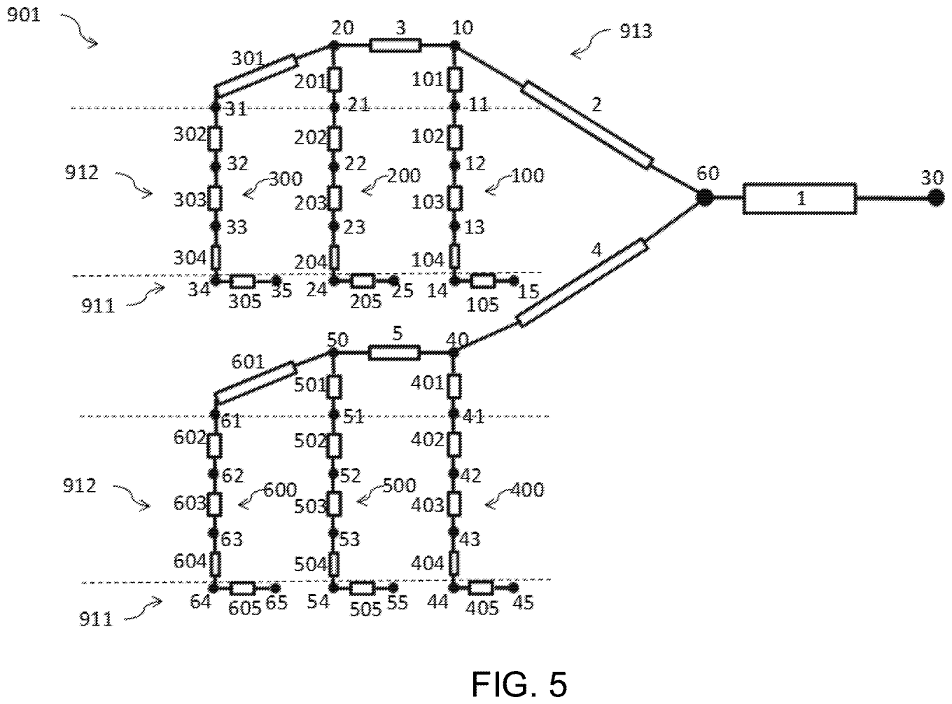

Please refer to FIGS. 1&5. FIG. 5 illustrates the analytical model 901 in accordance with another embodiment of the present invention.

The reservoir model 911 and the surface pipeline model 913 of the embodiment in accordance with FIG. 5 is similar to the reservoir model 911 and the surface pipeline model 913 of the embodiment in accordance with FIG. 3. And, a main difference between the plurality of well models 912 in accordance with FIG. 3 and the plurality of well models 912 in accordance with FIG. 5 comprises that each of the well models 100, 200, 300, 400, 500 and 600 comprises a choke connected with the surface pipeline model 913.

A choke 102 of the well model 100 is connected with the pipe 103 of the well model 100 at a node 12 and is connected with the pipe 101 of the surface pipeline model 913 at a node 11. A choke 202 of the well model 200 is connected with the pipe 203 of the well model 200 at a node 22 and is connected with the pipe 201 of the surface pipeline model 913 at a node 21. A choke 302 of the well model 300 is connected with the pipe 303 of the well model 300 at a node 32 and is connected with the pipe 301 of the surface pipeline model 913 at a node 31. A choke 402 of the well model 400 is connected with the pipe 403 of the well model 400 at a node 42 and is connected with the pipe 401 of the surface pipeline model 913 at a node 41. A choke 502 of the well model 500 is connected with the pipe 503 of the well model 500 at a node 52 and is connected with the pipe 501 of the surface pipeline model 913 at a node 51. A choke 602 of the well model 600 is connected with the pipe 603 of the well model 600 at a node 62 and is connected with the pipe 601 of the surface pipeline model 913 at a node 61.

A set of chokes [102, 202, 302, 402, 502, 602] is associated with a set of choke openings [C₁, C₂, C₃, C₄, C₅, C₆], and chokes 102, 202, 302, 402, 502 and 602 in the well models 100, 200, 300, 400, 500 and 600 are respectively associated with choke openings C₁, C₂, C₃, C₄, C s and C₆.

The optimization module 902 of the embodiment in accordance with FIG. 5 varies sets of variable parameters of the analytical model 901 in accordance with FIG. 5 and satisfies the set of pre-determined constraints to optimize the objective function of the resource production system.

In some embodiments, the sets of variable parameters comprise the set of flow rates [F₁, F₂, F₃, F₄, F₅, F₆] and the set of pump drive parameters [V₁, V₂, V₃, V₄, V₅, V₆], and running the optimization includes calculating pressures of each of the set of chokes [102, 202, 302, 402, 502, 602] based on the analytical model 901; in some embodiments, running the optimization further includes calculating the set of choke openings [C₁, C₂, C₃, C₄, C₅, C₆] based on the calculated pressures and the model of each of the set of chokes [102, 202, 302, 402, 502, 602].

In some embodiments, the pressures of each of the set of chokes [102, 202, 302, 402, 502, 602] comprises the pressures of the upstream side and the downstream side of each of the set of chokes [102, 202, 302, 402, 502, 602].

For example, the pressures of the choke 102 comprises the pressure of the upstream side (i.e., the pressure of the node 12) and the pressure of the downstream side (i.e., the pressure of the node 11).

Without considering the interference of commingling fluids in the surface pipeline, the pressure of the node 11 may be calculated based on the pressure at the node 30, the flow rate F₁ and the property of pipes 101, 2 and 1 (the property of pipes 101, 2 and 1 may be obtained from the surface pipeline model 913). With considering the interference of commingling fluids in the surface pipeline, the pressure of the node 11 may be calculated based on the pressure at the node 30, the set of flow rates [F₁, F₂, F₃, F₄, F₅, F₆], the surface pipeline model 913, the fluid property model and the fluid commingling model. The calculation of the pressure at the node 11 is similar with the calculation of the pressure at the node 13 of the embodiments in accordance with the FIG. 3, thus is not detailed herein.

Without considering the interference between wells, the pressure of the node 12 may be calculated based on the pressure at the node 15, the flow rate F₁, the pump drive parameter V₁ and the reservoir model 911. For example, the pressure at the node 14 is output by reservoir model 911 based on the pressure at the node 15 and the flow rate F₁; the pressure increment of the pump 104 is calculated based on the pump drive parameter V₁, the flow rate F₁ and the model of the pump 104; the pressure drop of the pipe 103 is calculated based on the flow rate F₁ and the property of the pipe 103; then, the pressure at the node 12 may be calculated based on the pressure at the node 14, the pressure increment of the pump 104 and the pressure drop of the pipe 103. In some embodiments, the pressure of the node 12 may be obtained directly from a pressure sensor located at the wellhead if without considering the interference between wells.

If the interference between wells is considered, the pressure of the node 12 may be calculated based on the pressure at the node 15, the set of flow rates [F₁, F₂, F₃, F₄, F₅, F₆], the pump drive parameter V₁ and the reservoir model 911. For example, the reservoir model 911 comprises a function for calculating the interference between neighboring wells and outputs the pressure at the node 14 based on the set of flow rates [F₁, F₂, F₃, F₄, F₅, F₆] and the pressure at the node 15. The calculations of the pressure increment of the pump 104 and the pressure drop of the pipe 103 are similar to what aforementioned and are not detailed herein.

Known the pressures at the node 11 and node 12, the pressure drop of the choke 102 is calculated and the choke opening C₁ of the choke 102 may be calculated based on the model of the choke 102 and the pressure drop utilizing, e.g., a root finding algorithm such as a binary search.

In some embodiments, the sets of variable parameters comprise the set of flow rates [F₁, F₂, F₃, F₄, F₅, F₆] and the set of choke openings [C₁, C₂, C₃, C₄, C₅, C₆], and running the optimization includes calculating pressures of each of the set of pumps [104, 204, 304, 404, 504, 604] based on the analytical model 901; in some embodiments, running the optimization further includes calculating the set of pump drive parameters [V₁, V₂, V₃, V₄, V₅, V₆] based on the calculated pressures and the model of each of the set of pumps [104, 204, 304, 404, 504, 604]. Details of these embodiments are not described herein as they are similar with the embodiments described as aforementioned.

The calculation of the choke openings C₂, C₃, C₄, C s and C₆ are similar with the calculation of the choke opening C₁.

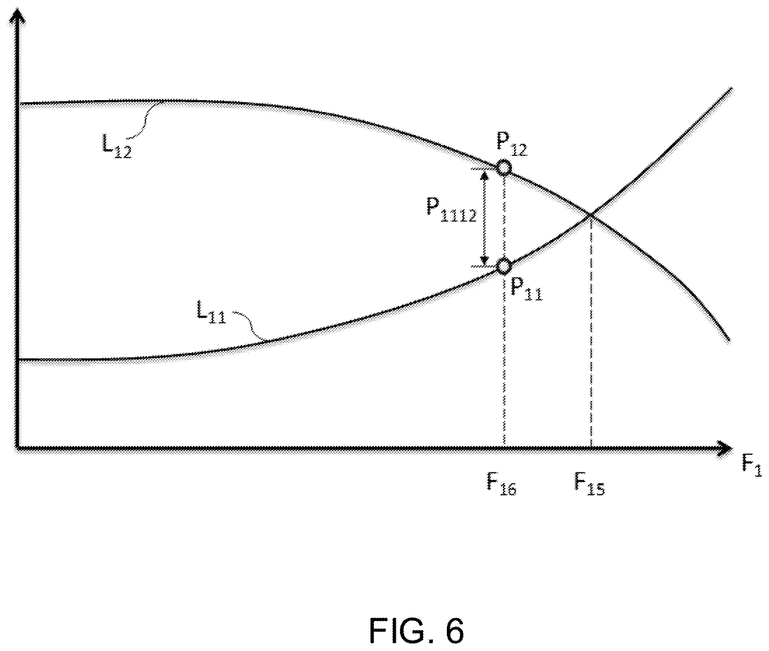

Please refer to FIGS. 5&6, wherein the X-axis of the coordinates shown in FIG. 6 indicates the flow rate F₁ and the Y-axis in FIG. 6 indicates pressure. Without considering the interference of commingling fluids in the surface pipeline and the interference between wells, a tendency of the change of pressure at the node 11 with respect to the change of flow rate F₁ is illustrated as line L₁₁ and the change of pressure at the node 12 with respect to the change of flow rate F₁ is illustrated as line Lie. The pressure at the node 11 increases while the flow rate F₁ increases, and the pressure at the node 12 drops while the flow rate F₁ increases. When F₁ is varied to F₁₆, the pressure P₁₁ and the pressure Pie may be calculated as aforementioned, then the pressure drop P₁₁₁₂ of the choke 102 is determined. Please be noted that, for ensuring that the pressure at the node 12 is larger than the pressure at the node 11, the finally obtained flow rate F₁ (i.e., the flow rate F₁ in the result of optimization) should be smaller than the flow rate F₁₅, at which the line L₁₁ intersects with the line L₁₂.

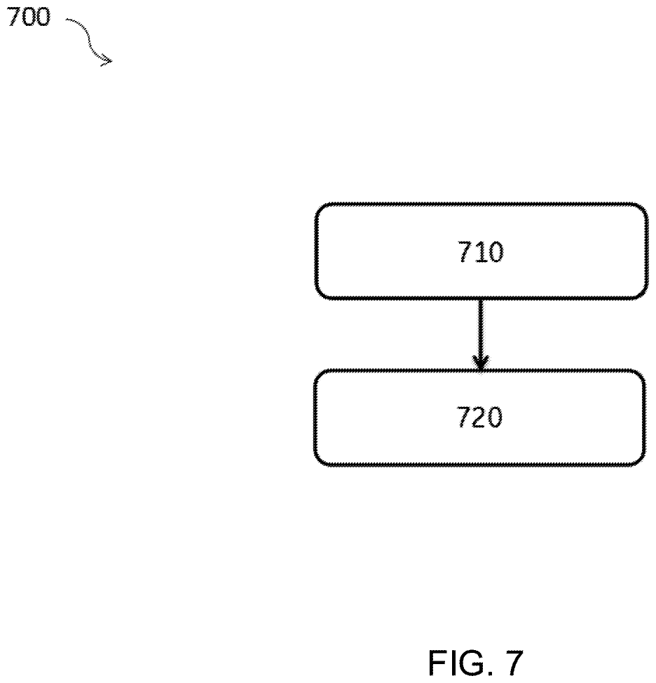

Please refer to FIGS. 1&7. FIG. 7 is a schematic flow diagram of an optimization method 700 for optimizing the objective function of the resource production system in accordance with an embodiment of the present invention. The optimization method 700 comprises a step 710 and a step 720.

In the step 710, an analytical model 901 of the resource production system is established. The analytical model 901 comprises a reservoir model 911, a plurality of well models 912 coupled to the reservoir model 911 and a surface pipeline model 913 coupled to the plurality of well models 912. The plurality of well models 912 comprise the first set of segments associated with a first set of operating parameters. In some embodiments, the analytical model 901 further comprises a fluid commingling model (not shown) and a fluid property model (not shown) associated with the surface pipeline model 913.

In the step 720, the set of variable parameters are varied and the set of pre-determined constraints is satisfied to optimize the objective function of the resource production system, wherein running the optimization includes calculating pressures of each of the first set of segments based on the analytical model 901. In some embodiments, running the optimization further includes calculating the first set of operating parameters based on the calculated pressures and the model of each of the first set of segments.

In some embodiments, the set of variable parameters comprises a set of flow rates associated with the plurality of well models 912, the first set of segments comprises a set of pumps and the first set of operating parameters comprises a set of pump drive parameters.

In some embodiments, the plurality of well models 912 further comprise a second set of segments associated with a second set of operating parameters, sets of variable parameters comprising the set of flow rates and the second set of segments are utilized in the step 720. In some embodiments, the first set of segments is the set of pumps and the second set of segments is the set of chokes; in some embodiments, the first set of segments is the set of chokes and the second set of segments is the set of pumps.

Please refer to FIGS. 1&7-8. In some embodiments, the step 720 comprises a step 721, a step 722 and a step 723.

In the step 721, an optimization of the objective function is performed and the termination criterion is evaluated to determine whether it is met. The evaluation of the termination criterion comprises that whether the optimized objective function satisfies the production target and whether the set of pre-determined constraints is satisfied. The optimization of the objective function comprises calculating pressures of each of the first set of segments based on the analytical model 901 with the set(s) of variable parameters and calculating the first set of operating parameters based on the calculated pressures of each of the first set of segments and the model of each of the first set of segments.

In some embodiments, the set of variable parameter comprises the set of flow rates, and the first set of operating parameters comprises the set of pump drive parameters. In some embodiments, the sets of variable parameters comprise the set of flow rates and one set of the set of pump drive parameters and the set of choke openings, the first set of operating parameters comprises the other set of the set of pump drive parameters and the set of choke openings.

If the termination criterion is not met, the set(s) of variable parameters is varied in the step 722 and the step 721 is performed again. In some embodiments, the set(s) of variable parameters is varied based on the set of pre-determined constraints to obtain feasible set(s) of variable parameters for performing the step 721 again.

If the termination criterion is met, in the step 723, the result of the optimization is obtained. The result of the optimization may comprise the finally varied set(s) of variable parameters and/or the first set of operating parameters.

Considering the interference between wells and in the surface pipeline, a better optimal result may be obtained. Moreover, by varying the set of flow rates (or the set of flow rates and one set of the set of pump drive parameters and the set of choke openings) to calculate the set of pump drive parameters (or calculate the other set of the set of pump drive parameters and the set of choke openings) rather than varying the set of pump drive parameters (or the set of pump drive parameters and the set of choke openings) to calculate the set of flow rates, and by calculating the pressures of a set of segments for each varied set of flow rates (or each varied set of flow rates and one set of the set of pump drive parameters and the set of choke openings) rather than utilizing a nodal analysis algorithm (e.g., for each varied set of operating parameters, calculates two curves indicating two kinds of tendencies of the change of pressure at one node with respect to the change of flow rate associated with the well model including the one node), the algorithm efficiency is greatly improved. For example, compared with utilizing the nodal analysis algorithm, a 25-fold reduction in computation time may be achieved by utilizing the algorithm in accordance with the embodiments of the present invention.

In some embodiments, the optimization apparatus 90 may be included in an optimization system, and the optimization system may further include a well management system for communicating with the plurality of wells. The optimization apparatus 90 provides the result of the optimization to the well management system, and the well management system communicates with the plurality of wells of the resource production system to perform a production optimization based on the result of the optimization.

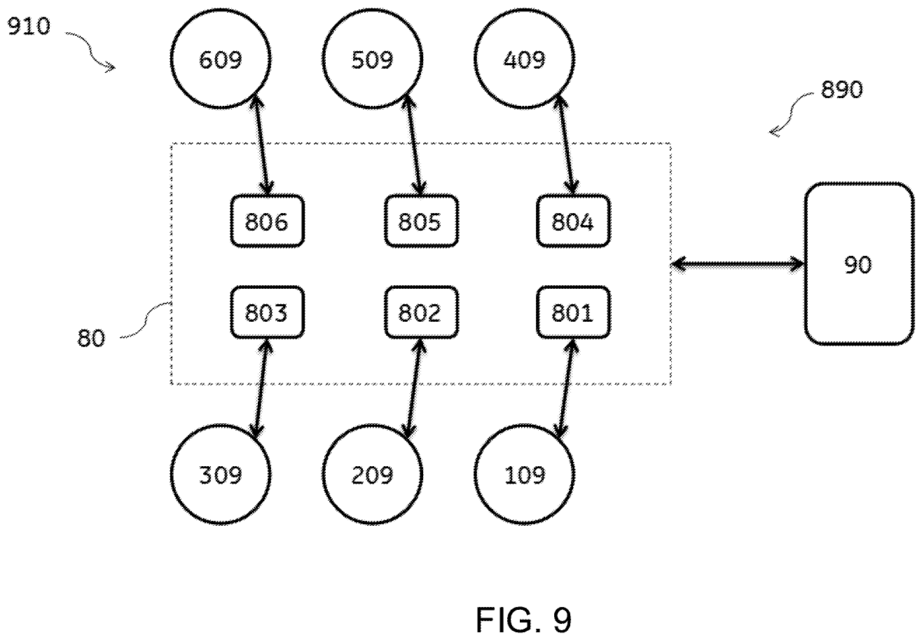

FIG. 9 illustrates a schematic view of an optimization system 890 communicated with a resource production system 910 in accordance with an embodiment of the present invention.

The resource production system 910 comprises a plurality of wells 109, 209, 309, 409, 509, 609 extended to an underground reservoir for artificially lifting fluids from the underground reservoir to the surface.

The optimization system 890 comprises a well management system 80 for communicating with the plurality of wells 109, 209, 309, 409, 509, 609 and the optimization apparatus 90 for communicating with the well management system 80. The well management system 80 may be integrated with the optimization apparatus 90, or the well management system 80 may communicate with the optimization apparatus 90 remotely. The optimization apparatus 90 may be a center server, distributed servers, or a combination thereof. The optimization apparatus 90 is described in the embodiments in accordance with FIG. 1-6 and is not detailed in the embodiment in accordance with FIG. 9.

The well management system 80 comprises a plurality of well management units 801, 802, 803, 804, 805, 806, each of which obtains data relating to a well. The well management units 801, 802, 803, 804, 805, 806 may obtain data relating to the well by utilizing, for example, multiple sensors. The data related to the well may comprise but are not limited to a temperature, a pressure, a flow rate of the well and etc.

The well management system 80 provides the data relating to wells 109, 209, 309, 409, 509, 609 to the optimization system 90. The optimization apparatus 90 may update the analytical model 901 (described in the embodiments in accordance with FIG. 1-6) in accordance with the data received from the well management system 80. And, if the result of the optimization is determined, the optimization system 90 may provide data including, for example one or more sets of operating parameters, to the well management system 80, so that the well management system 80 may operate operable assemblies such as pumps and chokes in the wells 109, 209, 309, 409, 509, 609 to achieve a production optimization.

While the disclosure has been illustrated and described in typical embodiments, it is not intended to be limited to the details shown, since various modifications and substitutions can be made without departing in any way from the spirit of the present disclosure. As such, further modifications and equivalents of the disclosure herein disclosed may occur to persons skilled in the art using no more than routine experimentation, and all such modifications and equivalents are believed to be within the spirit and scope of the disclosure as defined by the following claims.

1. An optimization apparatus for optimizing an objective function of a resource production system, comprising:
an analytical model of the resource production system configured to receive data from the resource production system, the analytical model comprising a reservoir model, a plurality of well models coupled to the reservoir model, and a surface pipeline model coupled to the plurality of well models, wherein the plurality of well models comprise a first set of segments associated with a first set of operating parameters; and
an optimization module configured to vary a set of variable parameters of the analytical model and satisfy a set of pre-determined constraints to optimize an objective function of the resource production system, wherein running the optimization includes calculating pressures of each of the first set of segments based on the analytical model.

2. The optimization apparatus of claim 1, wherein the objective function comprises an output of the resource production system, an energy consumption of the resource production system, a cost of operating the resource production system, or a benefit of the resource production system.

3. The optimization apparatus of claim 1, wherein the set of pre-determined constraints comprises a minimum or maximum threshold of the objective function, a range for a set of operating parameters of the analytical model, a range for a set of variable parameters of the analytical model, a range for a nodal pressure of a pre-determined node in the analytical model, a range for a fluid property of a pre-determined node in the analytical model, a range of flow rate of a pre-determined node in the analytical model, a range for power consumption associated with a pre-determined segment in the analytical model, or any combination thereof.

4. The optimization apparatus of claim 1, wherein the first set of operating parameters comprises a set of pump drive parameters and the set of variable parameters comprises a set of flow rates, the optimization module calculates the pressures of each of the first set of segments based on the analytical model with the set of flow rates, and calculates the first set of operating parameters based on the calculated pressures and the model of each of the first set of segments.

5. The optimization apparatus of claim 1, wherein the plurality of well models comprise a second set of segments associated with a second set of operating parameters, the set of variable parameters comprises a set of flow rates associated with the plurality of well models and the second set of operating parameters.

6. The optimization apparatus of claim 5, wherein the optimization module calculates the pressures of each of the first set of segments based on the analytical model with the set of flow rates and the second set of operating parameters, and calculates the first set of operating parameters based on the calculated pressures and the model of each of the first set of segments.

7. The optimization apparatus of claim 5 or 6, wherein the first set of segments comprises a set of pumps and the second set of segments comprises a set of chokes, or the first set of segments comprises a set of chokes and the second set of segments comprises a set of pumps.

8. The optimization apparatus of claim 1, wherein the optimization module comprises:
an analyzing unit configured to receive a feasible set of flow rates and calculate the first set of operating parameters based on the model of each of the first set of segments;
an optimizing unit configured to vary a set of flow rates associated with the plurality of well models to obtain the feasible set of flow rates and provide the feasible set of flow rates to the analyzing unit to obtain the calculated first set of operating parameters while satisfying the set of pre-determined constraints; and
an invoking unit configured to iteratively invoke the analyzing unit and the optimizing unit till a termination criterion is met.

9. The optimization apparatus of claim 1, wherein the analytical model comprises a fluid property model and a fluid commingling model associated with at least one of the reservoir model, the plurality of well models and the surface pipeline model, and the pressures of each of the first set of segments are calculated based on the analytical model with a set of flow rates associated with the plurality of well models, the surface pipeline model, the fluid commingling model and the fluid property model.

10. An optimization method for optimizing an objective function of a resource production system, comprising:
establishing an analytical model of the resource production system for receiving data from the resource production system, the analytical model comprising a reservoir model, a plurality of well models coupled to the reservoir model, and a surface pipeline model coupled to the plurality of well models, wherein the plurality of well models comprise a first set of segments associated with a first set of operating parameters; and
varying a set of variable parameters of the analytical model and satisfy a set of pre-determined constraints to optimize an objective function of the resource production system, wherein running the optimization includes calculating pressures of each of the first set of segments based on the analytical model.

11. An optimization system for a resource production system comprising a plurality of wells, comprising:
a well management system configured to communicate with the plurality of wells; and
an optimization apparatus configured to communicate with the well management system, comprising:
an analytical model of the resource production system configured to receive data from the resource production system, the analytical model comprising a reservoir model, a plurality of well models coupled to the reservoir model, and a surface pipeline model coupled to the plurality of well models, wherein the plurality of well models comprise a first set of segments associated with a first set of operating parameters;
an optimization module configured to vary a set of variable parameters of the analytical model and satisfy a set of pre-determined constraints to optimize an objective function of the resource production system, wherein running the optimization includes calculating pressures of each of the first set of segments based on the analytical model;
wherein, the optimization module provides a result of the optimization to the well management system, and the well management system communicates with the plurality of wells to perform a production optimization based on the result of the optimization.
